(19) United States
(12) Patent Application Publication
(10) Pub. No.: US 2006/0051969 A1
(43) Pub. Date: Mar. 9, 2006

(54) Semiconductor device fabrication method

(76) Inventors: Takahito Nakajima, Yokkaichi-Shi (JP); Yoshihiro Uozumi, Yokohama-Shi (JP); Mikie Miyasato, Yamato-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 11/199,241

(22) Filed: Aug. 9, 2005

(30) Foreign Application Priority Data
Aug. 10, 2004 (JP) 2004-233405

(51) Int. Cl. H01L 21/31

(52) U.S. Cl. 438/758

(57) ABSTRACT

According to the present invention, there is provided a semiconductor device fabrication method comprising: forming an interlayer dielectric film on a semiconductor substrate; removing a predetermined region of the interlayer dielectric film, and forming a film by depositing a conductive material on the semiconductor substrate and interlayer dielectric film so as to fill the removed region; planarizing the film such that the film has substantially the same height as the interlayer dielectric film, thereby burying the conductive material to form a first conductive layer; and performing processing using a dilute aqueous choline solution on an upper surface of the buried first conductive layer.

### CROSS REFERENCE TO RELATED APPLICATION

This application is based upon and claims benefit of priority under 35 USC §119 from the Japanese Patent Application No. 2004-233405, filed on Aug. 10, 2004, the entire contents of which are incorporated herein by reference.

### BACKGROUND OF THE INVENTION

The present invention relates to a semiconductor device fabrication method.

In the semiconductor fabrication step, an interlayer dielectric film is formed on a semiconductor substrate in which a semiconductor element such as a MISFET is formed, and a contact plug for making contact with the semiconductor substrate surface is formed in this interlayer dielectric film. Another interlayer dielectric film is formed on these interlayer dielectric film and contact plug.

The other interlayer dielectric film is coated with a photoresist, and the photoresist is exposed and developed to form a resist mask having a pattern which opens above the upper surface of the contact plug.

This resist mask is used as a mask to etch away the surface portion of the interlayer dielectric film by a predetermined depth, thereby forming an interconnection trench in this interlayer dielectric film, and exposing the upper surface of the contact plug.

After the resist mask is removed by oxidation, deposits such as the resist residue are removed by using an organic fluoric chemical prepared by adding NH₄F to an organic solvent.

When performed using this organic fluoric chemical, etching progresses in the lateral direction of the interconnection trench, and this increases the width of the trench. As a consequence, if a copper interconnection is formed to connect to the contact plug by burying copper in this trench, this copper interconnection becomes wider than the mask pattern. This makes the wiring resistance different from the design value, and produces variations in characteristics.

A reference pertaining to the removal of the resist residue is as follows.

PCT(WO) 2002-520812

### SUMMARY OF THE INVENTION

According to one aspect of the invention, there is provided a semiconductor device fabrication method comprising:

forming an interlayer dielectric film above a semiconductor substrate;

removing a predetermined region of the interlayer dielectric film, and forming a film by depositing a conductive material so as to fill the removed region;

planarizing the film such that the film has substantially the same height as the interlayer dielectric film, thereby burying the conductive material to form a first conductive layer; and

performing processing using a dilute aqueous choline solution on an upper surface of the buried first conductive layer.

The bottom of the removed region of the interlayer dielectric film is a surface of a semiconductor substrate, a conductive layer or a dielectric film, etc.

According to one aspect of the invention, there is provided a semiconductor device fabrication method comprising:

forming a first interlayer dielectric film above a semiconductor substrate;

removing a predetermined region of the first interlayer dielectric film, and forming a film by depositing a conductive material so as to fill the removed region;

planarizing the film such that the film has substantially the same height as the first interlayer dielectric film, thereby burying the conductive material to form a conductive layer;

forming a second interlayer dielectric film on the first interlayer dielectric film and buried conductive layer;

forming, on the second interlayer dielectric film, a mask having a pattern which opens above part or a whole of an upper surface of the conductive layer;

exposing the upper surface of the conductive layer by etching the second interlayer dielectric film by using the mask; and

performing processing using a dilute aqueous choline solution on the upper surface of the exposed conductive layer.

The bottom of the removed region of the first interlayer dielectric film is a surface of a semiconductor substrate, a conductive layer or a dielectric film, etc.

According to one aspect of the invention, there is provided a semiconductor device fabrication method comprising:

forming an interlayer dielectric film above a semiconductor substrate;

removing a plug formation region for forming a plug of the interlayer dielectric film;

removing an interconnection formation region for forming an interconnection of the interlayer dielectric film, thereby removing the interlayer dielectric film to a predetermined depth;

forming a film by depositing a conductive material so as to fill the plug formation region and interconnection formation region;

planarizing the film such that the film has substantially the same height as the interlayer dielectric film, thereby forming the plug and interconnection; and

processing the interconnection by using a dilute aqueous choline solution.

The bottom of the removed plug formation region of the interlayer dielectric film is a surface of a semiconductor substrate, a conductive layer, or a dielectric film, etc.

According to one aspect of the invention, there is provided a semiconductor device fabrication method comprising:

performing processing using a dilute aqueous choline solution on an upper surface of a buried conductive layer in an interlayer dielectric film formed above a semiconductor substrate.

### BRIEF DESCRIPTION OF THE DRAWINGS

FIG. 1 is a longitudinal sectional view showing an element sectional structure in a predetermined step of a semiconductor device fabrication method according to the first embodiment of the present invention;

FIG. 2 is a longitudinal sectional view showing an element sectional structure in a predetermined step of the semiconductor device fabrication method;

FIG. 3 is a longitudinal sectional view showing an element sectional structure in a predetermined step of the semiconductor device fabrication method;

FIG. 4 is a longitudinal sectional view showing an element sectional structure in a predetermined step of the semiconductor device fabrication method;

FIG. 5 is a longitudinal sectional view showing an element sectional structure in a predetermined step of the semiconductor device fabrication method;

FIG. 6 is a longitudinal sectional view showing an element sectional structure in a predetermined step of the semiconductor device fabrication method;

FIG. 7 is a longitudinal sectional view showing an element sectional structure in a predetermined step of the semiconductor device fabrication method;

FIG. 8 is a longitudinal sectional view showing an element sectional structure in a predetermined step of the semiconductor device fabrication method;

FIG. 9 is a longitudinal sectional view showing an element sectional structure in a predetermined step of the semiconductor device fabrication method;

FIG. 10 is a longitudinal sectional view showing an element sectional structure in a predetermined step of the semiconductor device fabrication method;

FIG. 11 is a graph showing the film thickness of a tungsten oxide film before and after processing is performed using a dilute aqueous choline solution;

FIG. 12 is a view showing the relationship between an interlayer dielectric film and its etching amount;

FIG. 13 is a longitudinal sectional view showing an element sectional structure in a predetermined step of a semiconductor device fabrication method according to the second embodiment of the present invention;

FIG. 14 is a longitudinal sectional view showing an element sectional structure in a predetermined step of the semiconductor device fabrication method;

FIG. 15 is a longitudinal sectional view showing an element sectional structure in a predetermined step of the semiconductor device fabrication method;

FIG. 16 is a longitudinal sectional view showing an element sectional structure in a predetermined step of the semiconductor device fabrication method;

FIG. 17 is a longitudinal sectional view showing an element sectional structure in a predetermined step of the semiconductor device fabrication method;

FIG. 18 is a longitudinal sectional view showing an element sectional structure in a predetermined step of the semiconductor device fabrication method;

FIG. 19 is a longitudinal sectional view showing an element sectional structure in a predetermined step of a semiconductor device fabrication method according to the third embodiment of the present invention;

FIG. 20 is a longitudinal sectional view showing an element sectional structure in a predetermined step of the semiconductor device fabrication method;

FIG. 21 is a longitudinal sectional view showing an element sectional structure in a predetermined step of the semiconductor device fabrication method;

FIG. 22 is a longitudinal sectional view showing an element sectional structure in a predetermined step of the semiconductor device fabrication method;

FIG. 23 is a longitudinal sectional view showing an element sectional structure in a predetermined step of the semiconductor device fabrication method;

FIG. 24 is a longitudinal sectional view showing an element sectional structure in a predetermined step of the semiconductor device fabrication method;

FIG. 25 is a longitudinal sectional view showing an element sectional structure in a predetermined step of the semiconductor device fabrication method;

FIG. 26 is a longitudinal sectional view showing an element sectional structure in a predetermined step of the semiconductor device fabrication method;

FIG. 27 is a longitudinal sectional view showing an element sectional structure in a predetermined step of the semiconductor device fabrication method.

### DETAILED DESCRIPTION OF THE INVENTION

Embodiments of the present invention will be described below with reference to the accompanying drawings.

### (1) First Embodiment

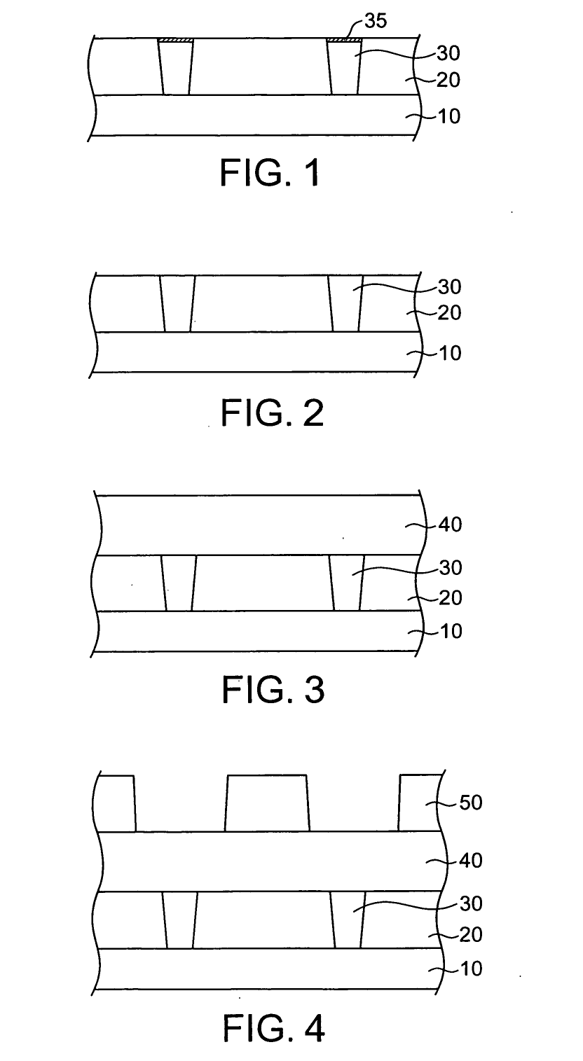

FIGS. 1 to 10 illustrate a semiconductor device fabrication method according to the first embodiment of the present invention. As shown in FIG. 1, an interlayer dielectric film 20 made of, e.g., a silicon oxide (SiO₂) film is formed on a semiconductor substrate 10 in which a semiconductor element such as a MISFET (not shown) is formed, and the surface of the interlayer dielectric film 20 is planarized by CMP (Chemical Mechanical Polishing) or the like.

To avoid the problem of a wiring delay, the interlayer dielectric film 20 may also be a low-dielectric-constant film (low-k film) having a dielectric constant lower than that of a silicon oxide (SiO₂) film. As this low-dielectric-constant film, it is possible to use an organic low-dielectric-constant film made of an organic material, an SiOF film formed by doping fluorine in a silicon oxide (SiO₂) film, an SiOC film formed by doping a few % of carbon in a silicon oxide (SiO₂) film, a porous SiOC film, a porous organic film, or an SiCN film. It is also possible to combine two or more types of these films by stacking them.

Contact holes are formed by removing predetermined regions of the interlayer dielectric film 20. The bottom of the removed region of the interlayer dielectric film 20 can be a surface of the semiconductor substrate 10, a conductive layer or a dielectric film formed on the substrate 10, etc. After that, a tungsten film is formed by depositing tungsten (W) as a conductive material on the semiconductor substrate 10 and interlayer dielectric film 20 so as to fill the contact holes.

This tungsten film is then planarized to form tungsten plugs 30 in the interlayer dielectric film 20, as plugs which connect the surface of the semiconductor substrate 10 to an interconnecting layer. Note those plugs are not limited to the tungsten plugs 30, and it is also possible to form polysilicon plugs, or other metal plugs such as titanium plugs. Alternatively, plugs containing at least one of tungsten and titanium may also be formed. When metal plugs made of tungsten or the like are to be formed, a barrier metal is desirably stacked as an underlying layer.

For example, as a barrier metal of tungsten, titanium (Ti) and titanium nitride (TiN) can be used singly or in combination.

By natural oxidation when or after the tungsten film is planarized, the upper surfaces of the tungsten plugs 30 oxidize to form tungsten oxide films 35 on them. The tungsten oxide films 35 are desirably removed because they increase the contact resistance.

As shown in FIG. 2, the upper surfaces of the tungsten plugs 30 are processed by using a dilute aqueous choline solution prepared by diluting choline (2-hydroxyethyltrimethyl ammonium hydroxide) with pure water, thereby etching away the tungsten oxide films 35. When this processing is performed using the dilute aqueous choline solution, deposits such as the resist residue can also be removed.

This makes it possible to avoid the rise of the contact resistance, and thereby prevent variations in characteristics and increase the yield. Note that processing conditions for effectively removing the tungsten oxide films 35 will be explained later.

As shown in FIG. 3, an interlayer dielectric film 40 made of, e.g., a silicon oxide (SiO₂) film is deposited on the interlayer dielectric film 20 and tungsten plugs 30. Similar to the interlayer dielectric film 20, the interlayer dielectric film 40 may also be a low-dielectric-constant film (low-k film) having a dielectric constant lower than that of a silicon oxide (SiO₂) film. As this low-dielectric-constant film, it is possible to use, e.g., an organic low-dielectric-constant film, SiOF film, SiOC film, porous SiOC film, porous organic film, or SiCN film. Two or more types of these films may also be combined by stacking them.

As shown in FIG. 4, the interlayer dielectric film 40 is coated with a photoresist, and the photoresist is exposed and developed to form a resist mask 50 having a pattern which opens above the upper surfaces of the tungsten plugs 30.

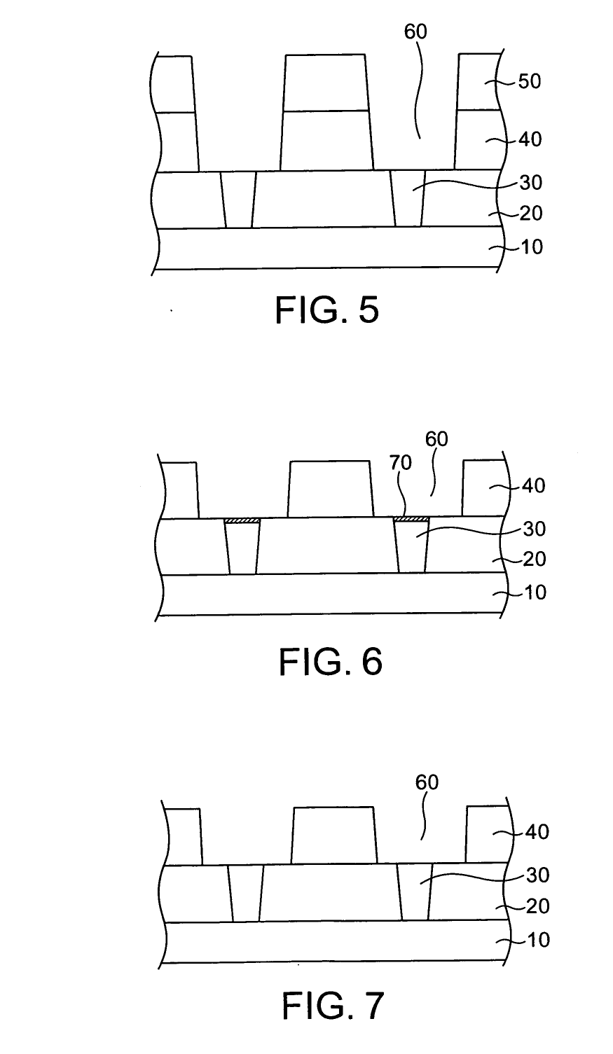

As shown in FIG. 5, the resist mask 50 is used as a mask to etch away the interlayer dielectric film 40 to a depth on substantially the same level as the upper ends of the tungsten plugs 30, thereby forming interconnection trenches 60 in the interlayer dielectric film 40, and exposing the upper surfaces of the tungsten plugs 30.

As shown in FIG. 6, ashing is performed to remove the resist mask 50 by oxidation. During this ashing, the exposed upper surfaces of the tungsten plugs 30 oxidize to form tungsten oxide films 70 on them. The tungsten oxide films 70 are desirably removed because they increase the contact resistance.

It is also possible to deposit a different film serving as a hard mask on the interlayer dielectric film 40 shown in FIG. 4, process this hard mask by using the resist mask 50 to once transfer the pattern of the resist mask 50 to the hard mask, and then remove the resist mask 50 by ashing or the like. In this case, the upper surfaces of the tungsten plugs 30 can be exposed by removing, by using the hard mask as a mask, the interlayer dielectric film 40 to the depth on substantially the same level as the upper ends of the tungsten plugs 30. During this processing, tungsten oxide films 70 are formed by natural oxidation on the upper surfaces of the tungsten plugs 30.

As shown in FIG. 7, the tungsten oxide films 70 are etched away by processing the upper surfaces of the tungsten plugs 30 by using a dilute aqueous choline solution prepared by diluting choline with deionozed water.

Methods of removing the tungsten oxide films 70 by using the dilute aqueous choline solution are as follows. In single wafer processing, the tungsten oxide films 70 are removed by spraying the dilute aqueous choline solution against the upper surfaces of the tungsten plugs 30. In batch processing, the tungsten oxide films 70 are removed by dipping the semiconductor substrate 10 into the dilute aqueous choline solution.

As processing conditions for effectively removing the tungsten oxide films 70, the concentration of the dilute aqueous choline solution is desirably 0.01 to 10 wt %. Especially in single wafer processing, the concentration of the dilute aqueous choline solution is desirably 0.1 to 0.5 wt %, and the temperature is desirably 40° C. to 80° C. However, the temperature of the dilute aqueous choline solution need only be 20° C. to 100° C.

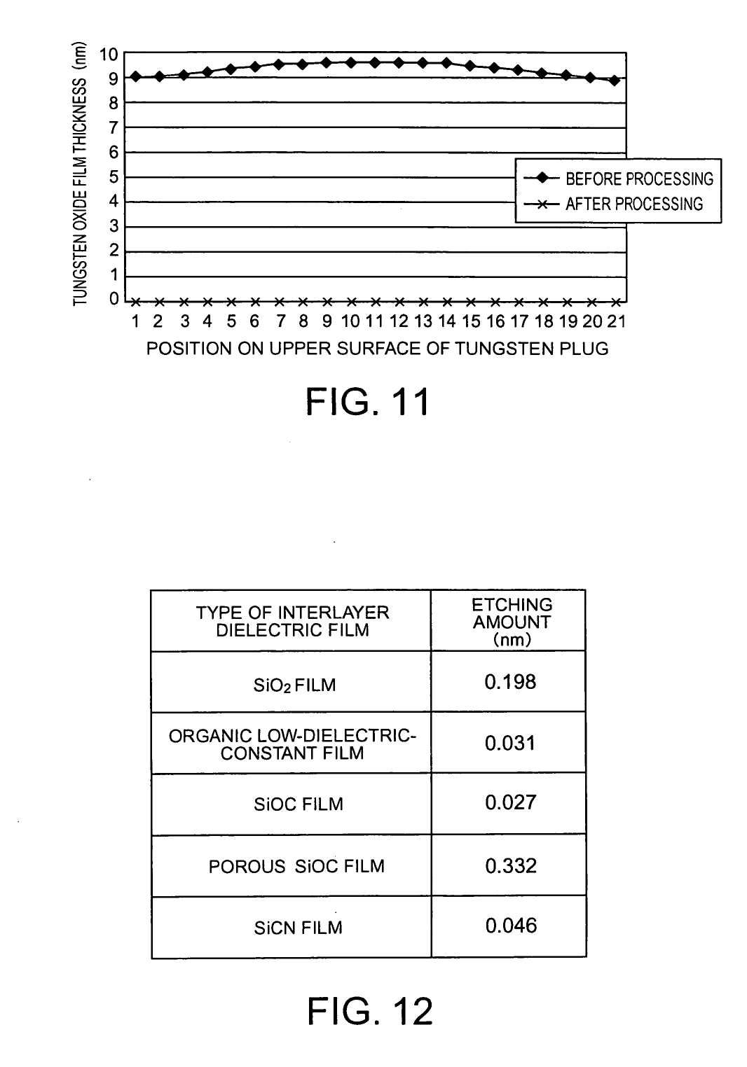

For example, when processing is performed at a temperature of 80° C. for 90 sec by using a dilute aqueous choline solution having a concentration of 0.1 to 0.5 wt %, as shown in FIG. 11, the tungsten oxide films 70 can be removed by about 9 nm. Referring to FIG. 11, the abscissa indicates a position in the radial direction on a circular substrate surface 200 mm in diameter. On a line passing through the center of the substrate, one end point is position 1, the center is position 11, and the other end point is position 21.

That is, as shown in FIG. 11, the film thickness of the tungsten oxide films 70 was about 9 nm before processing was performed using the dilute aqueous choline solution, and about 0 nm after that.

When the dilute aqueous choline solution is used as an etching solution, the tungsten oxide films 70 are etched more easily than the silicon oxide (SiO₂) film forming the interlayer dielectric film 40, because the etching selectivity is high, i.e., the etching rate of the former are higher than those of the latter.

Accordingly, when, for example, processing is performed at a temperature of 80° C. for 120 sec by using a dilute aqueous choline solution having a concentration of 0.1 to 0.5 wt %, the etching amount of the tungsten oxide films 70 is about 9 nm, whereas the etching amount of the interlayer dielectric film 40 can be decreased to 1 nm or less, as shown in FIG. 12, regardless of the type of the interlayer dielectric film 40.

More specifically, the etching amount of the interlayer dielectric film 40 is 0.198 nm when the interlayer dielectric film 40 is a silicon oxide (SiO₂) film, 0.031 nm when it is an organic low-dielectric-constant film, 0.027 nm when it is an SiOC film, 0.332 nm when it is a porous SiOC film, and 0.046 nm when it is an SiCN film.

By contrast, when an organic fluoric chemical is used as an etching solution, the etching rate of the interlayer dielectric film increases, so the etching amount of the interlayer dielectric film also increases. Therefore, when, for example, processing is performed for 120 sec by using an organic fluoric chemical, the etching amount of the interlayer dielectric film is about 2 to 3 nm if it is a silicon oxide (SiO₂) film.

When a dilute aqueous choline solution is used as an etching solution as described above, the tungsten oxide films 70 can be removed, and the etching amount of the interlayer dielectric film 40 can be reduced. Accordingly, the tungsten films 70 can be removed without increasing the width of the interconnection trenches 60 formed in the interlayer dielectric film 40, i.e., without increasing the width of copper interconnections to be formed later.

Note that in single wafer processing, hot water may also be sprayed together with the dilute aqueous choline solution when it is sprayed. In this case, the temperature of the hot water can be selected from room temperature to 100° C.

Also, by adding a slight amount of hydrogen fluoride (HF) or a fluorine compound (e.g., ammonium fluoride (NH₄F) or an organic fluorine compound) to the dilute aqueous choline solution, it is possible to remove those portions of the surfaces of the interlayer dielectric films 20 and 40, which are modified by various processes such as the etching step and ashing step. It is also possible to perform the process using dilute HF simultaneously with the process using the dilute aqueous choline solution, or to sequentially perform these processes. In this case, the HF concentration is preferably 10 wt % or less, and particularly preferably, 0.01 to 0.1 wt %, in order to suppress etching of the interlayer dielectric films. When processes were actually sequentially performed for 30 sec by using HF having a concentration of about 0.05 wt % and for 30 sec by using an aqueous choline solution having a concentration of about 0.1 wt %, the resist residue was removed better.

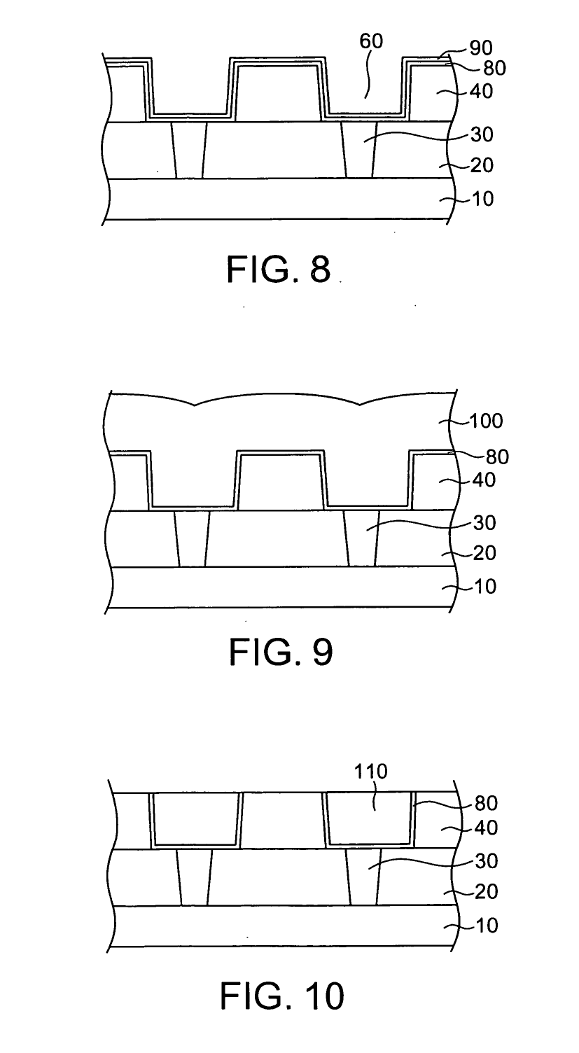

As shown in FIG. 8, a barrier metal film 80 and a seed copper (Cu) film 90 serving as a seed layer for plating are sequentially formed on all the surfaces of the interlayer dielectric films 20 and 40 by sputtering. After that, as shown in FIG. 9, a film mainly containing copper is formed on the entire surface by plating, thereby forming the barrier metal film 80 and a copper film 100.

As this barrier metal, tantalum (Ta), tantalum nitride (TaN), titanium (Ti), titanium nitride (TiN), and the like can be used singly or in combination.

As shown in FIG. 10, the barrier metal film 80 and copper film 100 are polished by CMP to form copper interconnections 110. In this manner, the copper interconnections 110 having the same width as the photomask can be formed, so the wiring resistance can be made equal to the design value. Also, the spacing between the adjacent copper interconnections 110 can be ensured, so a shortcircuit between them can be avoided. Note that metal interconnections are not limited to the copper interconnections 110, and it is also possible to form metal interconnections by using a material containing at least one of aluminum (Al), tungsten, and copper, or by using another metal.

Interconnections may also be formed instead of forming the plugs 30 on the semiconductor substrate 10. Alternatively, both plugs and interconnections may also be formed on the semiconductor substrate 10.

In addition, instead of the copper interconnections 110, plugs or both interconnections and plugs may also be formed.

Furthermore, the material of the copper interconnections 110 or the plugs or both the plugs and interconnections formed instead of the copper interconnections is not limited to copper. That is, these interconnections and plugs can be formed by using a material containing at least one of metal materials such as tungsten, titanium, tantalum, and aluminum, or by using another film.

### (2) Second Embodiment

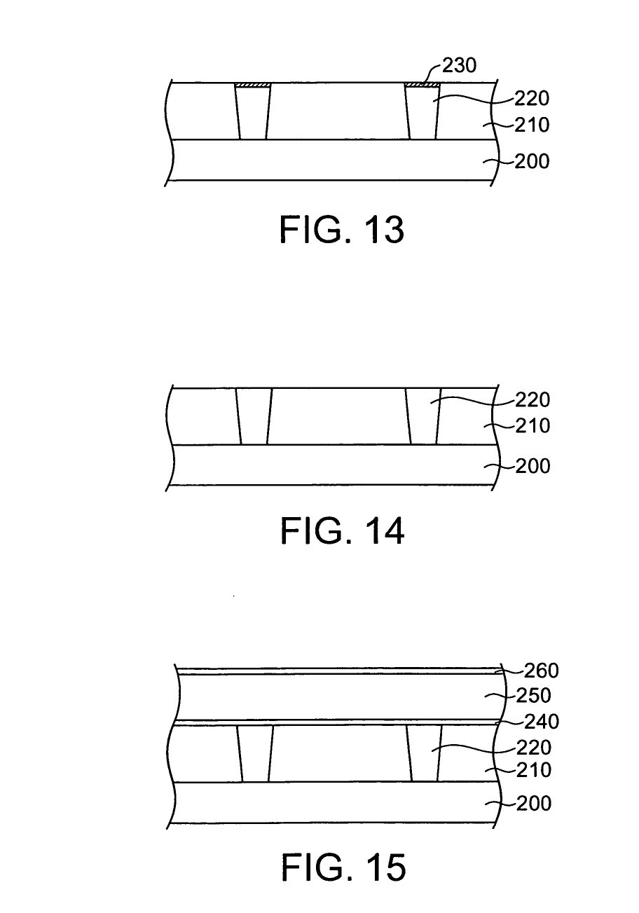

FIGS. 13 to 18 illustrate a semiconductor device fabrication method according to the second embodiment of the present invention. First, as shown in FIG. 13, an interlayer dielectric film 210 made of, e.g., a silicon oxide (SiO₂) film is formed on a semiconductor substrate 200, and the surface of the interlayer dielectric film 210 is planarized by CMP or the like.

Contact holes are formed by removing predetermined regions of the interlayer dielectric film 210.

The bottom of the removed region of the interlayer dielectric film 210 can be a surface of the semiconductor substrate 200, a conductive layer or a dielectric film formed on the substrate 200, etc. After that, a tungsten (W) film is deposited on the semiconductor substrate 200 and interlayer dielectric film 210 so as to fill the contact holes. This tungsten film is then planarized to form tungsten plugs 220 as contact plugs in the interlayer dielectric film 210.

As a barrier metal of tungsten, titanium (Ti), titanium nitride (TiN), and the like can be used singly or in combination.

By natural oxidation when or after the tungsten film is planarized, the upper surfaces of the tungsten plugs 220 oxidize to form tungsten oxide films 230 on them. The tungsten oxide films 230 are desirably removed because they increase the contact resistance.

As shown in FIG. 14, as in the first embodiment, the upper surfaces of the tungsten plugs 220 are processed by using a dilute aqueous choline solution prepared by diluting choline with deionozed water, thereby etching away the tungsten oxide films 230. This makes it possible to avoid the rise of the contact resistance, and thereby prevent variations in characteristics and increase the yield. Note that processing conditions and the like for effectively removing the tungsten oxide films 230 are the same as in the first embodiment.

As shown in FIG. 15, a barrier metal film 240 is formed on the interlayer dielectric film 210 and tungsten plugs 220 by sputtering. After that, an aluminum (Al) film 250 as an interconnecting material is formed on the barrier metal film 240, and a barrier metal film 260 is formed on the aluminum (Al) film 250.

In the formation of the barrier metal films 240 and 260, titanium (Ti), titanium nitride (TiN), and the like can be used singly or in combination.

Note that the film of the interconnecting material formed on the interlayer dielectric film 210 and tungsten plugs 220 via the barrier metal film 240 is not limited to the aluminum (Al) film 250, and it is also possible to form a film of various interconnecting materials such as tungsten. Note also that, of the barrier metal films 240 and 260 as the lower and upper layers, it is not particularly necessary to form the barrier metal film 260 as the upper layer.

As shown in FIG. 16, the barrier metal film 260 is coated with a photoresist, and the photoresist is exposed and developed to form a resist mask 270 having a pattern corresponding to the tungsten plugs 220.

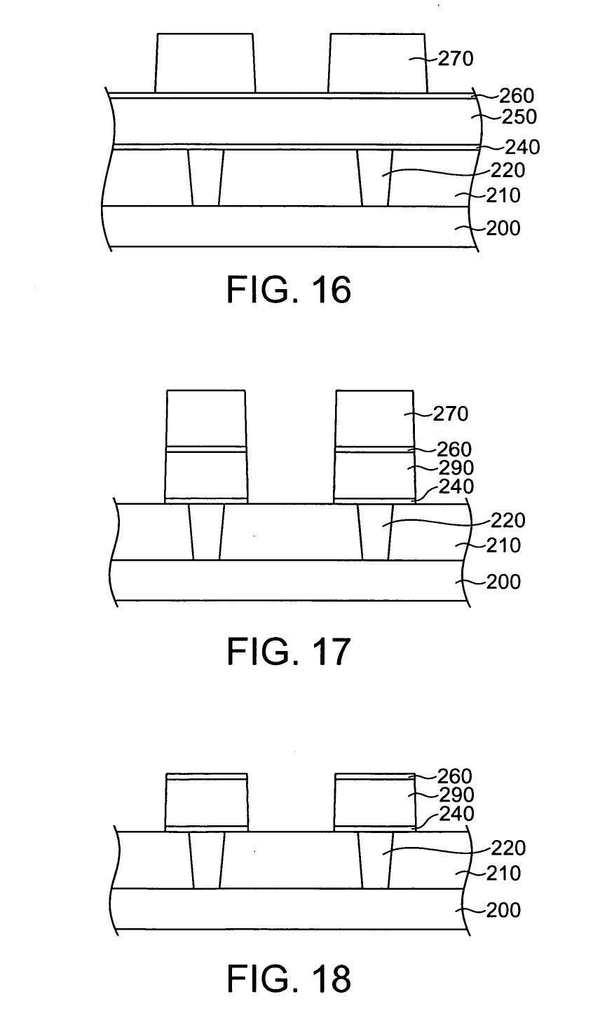

As shown in FIG. 17, the resist mask 270 is used as a mask to etch away desired regions of the barrier metal film 240, aluminum (Al) film 250, and barrier metal film 260, thereby forming aluminum interconnections 290 on the tungsten plugs 220.

As shown in FIG. 18, ashing is performed to remove the resist mask 270 by oxidation. Furthermore, tungsten plugs and aluminum interconnections are sequentially formed on the aluminum interconnections 290 to stack aluminum interconnections, thereby forming multilayered interconnections.

In this embodiment as described above, it is possible to avoid the rise of the contact resistance, and thereby prevent variations in characteristics and increase the yield.

Although the interconnections 290 are formed on the upper surfaces of the plugs 220 in this embodiment, plugs may also be formed on the upper surfaces of the plugs, instead of the interconnections.

### (3) Third Embodiment

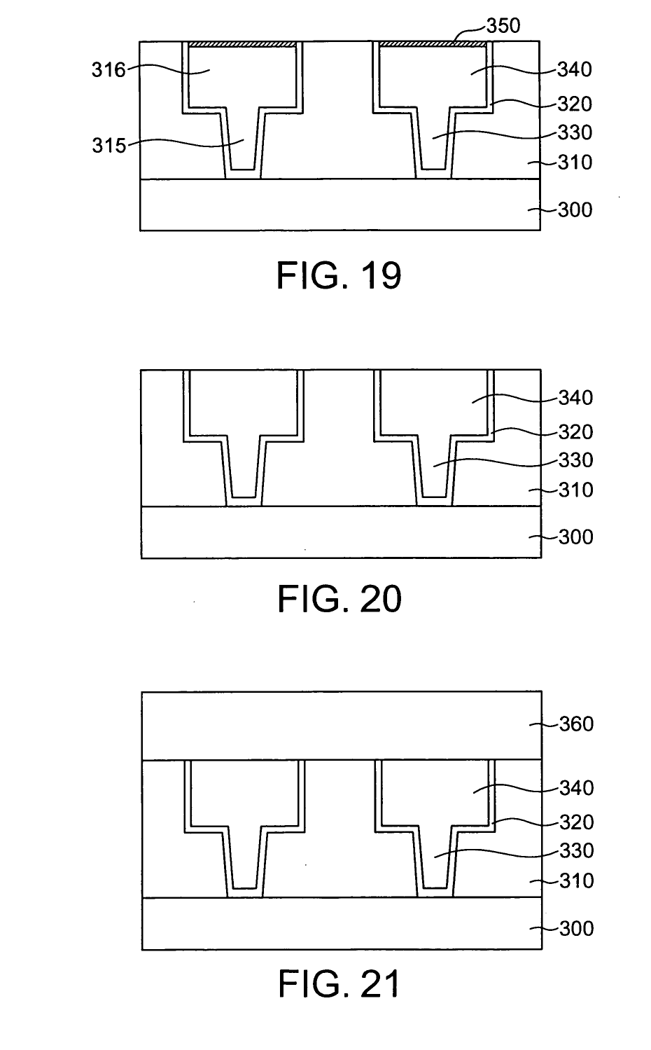

FIGS. 19 to 27 illustrate a semiconductor device fabrication method according to the third embodiment of the present invention. First, as shown in FIG. 19, an interlayer dielectric film 310 made of, e.g., a silicon oxide (SiO₂) film is formed on a semiconductor substrate 300, and the surface of the interlayer dielectric film 310 is planarized by CMP or the like.

A resist mask for forming contact holes is formed on the interlayer dielectric film 310. This resist mask is used as a mask to etch away plug formation regions for forming plugs of the interlayer dielectric film 310, thereby forming contact holes 315. After that, the resist mask for contact hole formation is removed.

Then, a resist mask for forming interconnection trenches is formed. After an etching time is designated, this resist mask is used to further etch away interconnection formation regions for forming interconnections of the interlayer dielectric film 310, thereby removing the interlayer dielectric film 310 to a predetermined depth to form interconnection trenches 316. After that, the resist mask for forming interconnection trenches is removed.

The bottom of the removed interconnection trenches or plug formation region of the interlayer dielectric film 310 can be a surface of the semiconductor substrate 300, a conductive layer or a dielectric film formed on the substrate 300, etc.

A barrier metal film 320 is formed on the inner surfaces of the contact holes 315 and interconnection trenches 316, and a tungsten (W) film is deposited to bury the barrier metal film 320. The barrier metal film 320 and tungsten film are then planarized to form tungsten plugs 330 as contact plugs and tungsten interconnections 340 in the interlayer dielectric film 310.

In the formation of the barrier metal film 320, titanium (Ti), titanium nitride (TiN), and the like can be used singly or in combination.

By natural oxidation when or after the tungsten film is planarized, the upper surfaces of the tungsten interconnections 340 oxidize to form tungsten oxide films 350 on them. The tungsten oxide films 350 are desirably removed because they increase the contact resistance.

As shown in FIG. 20, the upper surfaces of the tungsten interconnections 340 are processed by using a dilute aqueous choline solution prepared by diluting choline with deionozed water, thereby etching away the tungsten oxide films 350. This makes it possible to avoid the rise of the contact resistance, and thereby prevent variations in characteristics and increase the yield. Note that processing conditions and the like for effectively removing the tungsten oxide films 350 are the same as in the first embodiment.

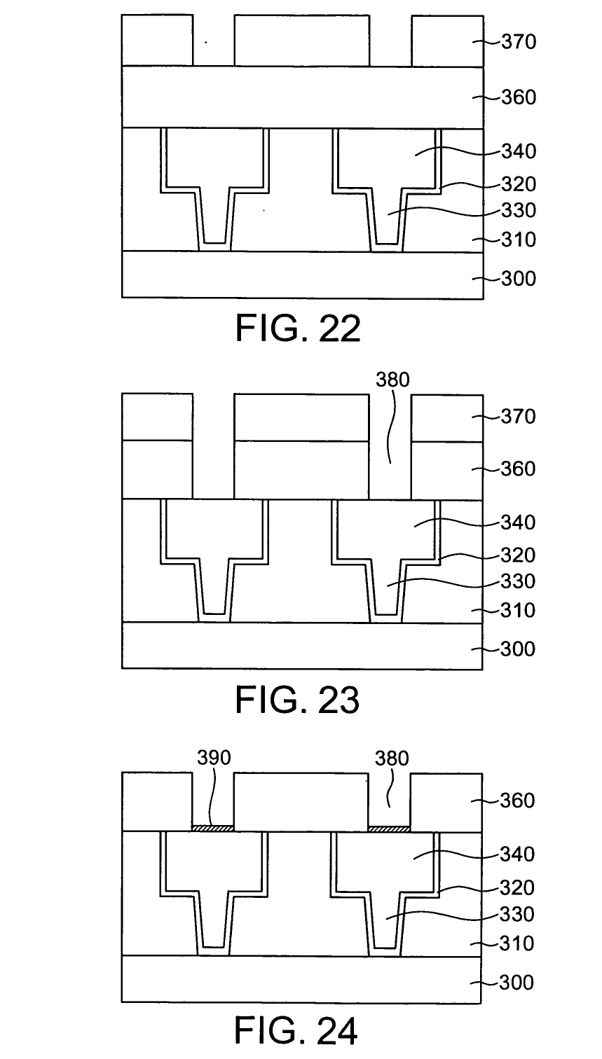

As shown in FIG. 21, an interlayer dielectric film 360 made of, e.g., a silicon oxide (SiO₂) film is deposited on the interlayer dielectric film 310, barrier metal film 320, and tungsten interconnections 340. As shown in FIG. 22, the interlayer dielectric film 360 is coated with a photoresist, and the photoresist is exposed and developed to form a resist mask 370 having a pattern which opens above the upper surfaces of the tungsten interconnections 340.

In the formation of the interlayer dielectric film, it is also possible to use a low-dielectric-constant film such as an organic low-dielectric-constant film, SiOF film, SiOC film, porous SiOC film, SiCN film, or porous organic film. It is also possible to combine two or more types of these films by stacking them.

As shown in FIG. 23, the resist mask 370 is used as a mask to etch away the interlayer dielectric film 360 to a depth on substantially the same level as the upper ends of the tungsten interconnections 340, thereby forming contact holes 380 in the interlayer dielectric film 360, and partially exposing the upper surfaces of the tungsten interconnections 340.

As shown in FIG. 24, ashing for removing the resist mask 370 by oxidation is performed. During this ashing, the exposed upper surfaces of the tungsten interconnections 340 oxidize to form tungsten oxide films 390 on portions of the upper surfaces of the tungsten interconnections 340. The tungsten oxide films 390 are desirably removed because they increase the contact resistance.

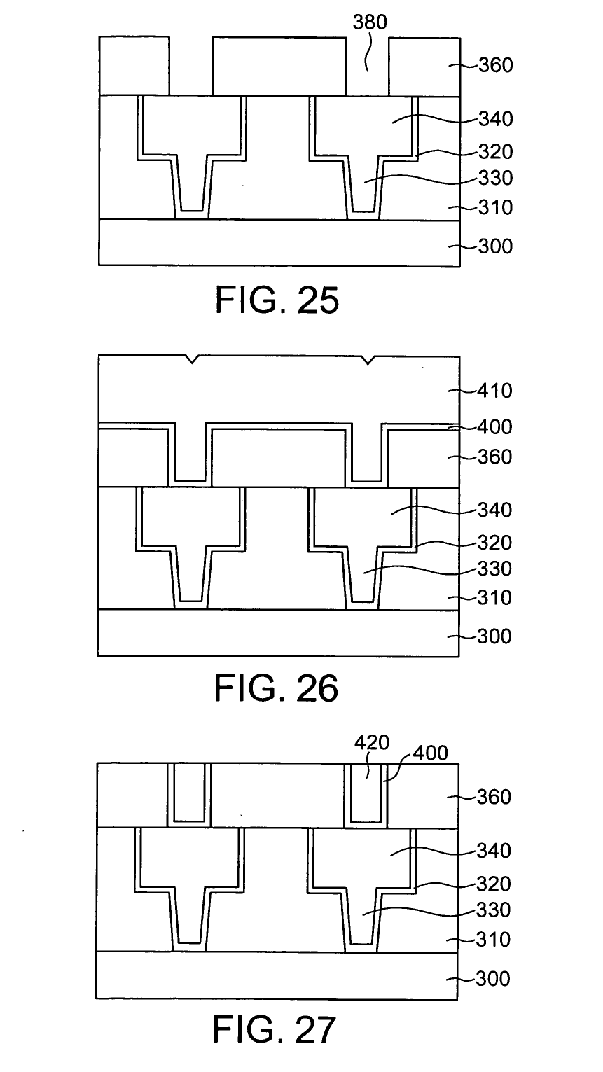

As shown in FIG. 25, the upper surfaces of the tungsten interconnections 340 are processed by using a dilute aqueous choline solution prepared by diluting choline with deionozed water, thereby etching away the tungsten oxide films 390. Note that practical processing conditions and the like for effectively removing the tungsten oxide films 390 are the same as in the first embodiment.

When the dilute aqueous choline solution is used as an etching solution, it is possible to remove the tungsten oxide films 390, and, as in the first embodiment, reduce the etching amount of the interlayer dielectric film 360. Accordingly, the tungsten oxide films 390 can be removed without increasing the width of the contact holes 380 formed in the interlayer dielectric film 360, i.e., the width of tungsten plugs to be formed later.

As shown in FIG. 26, a barrier metal film 400 is formed on the interlayer dielectric film 360 and tungsten interconnections 340 by sputtering, and a tungsten film 410 is formed on the entire surface by CVD.

As shown in FIG. 27, the barrier metal film 400 and tungsten film 410 are polished by CMP to form tungsten plugs 420. This makes it possible to form the tungsten plugs 420 having a width corresponding to the photomask, and prevent variations in characteristics.

### (4) Other Embodiments

Note that the above embodiments are merely examples, and do not limit the present invention. For example, when the tungsten plugs 30 or 220 or the tungsten interconnections 340 are processed by using a dilute aqueous choline solution having a concentration of 0.1 to 0.5 wt %, the temperature is desirably 20° C. to 100° C., and can be freely selected where necessary.

It is also possible to add, to the dilute aqueous choline solution, a slight amount of HF or a fluorine compound, a surfactant for improving the wettability, an organic solvent for improving the resist removability, and the like.

The semiconductor device fabrication methods of the above embodiments can prevent variations in characteristics and increase the yield.

What is claimed is:

1. A semiconductor device fabrication method comprising:
forming an interlayer dielectric film above a semiconductor substrate;
removing a predetermined region of the interlayer dielectric film, and forming a film by depositing a conductive material so as to fill the removed region;
planarizing the film such that the film has substantially the same height as the interlayer dielectric film, thereby burying the conductive material to form a first conductive layer; and
performing processing using a dilute aqueous choline solution on an upper surface of the buried first conductive layer.

2. A method according to claim 1, further comprising:
forming a film by depositing a conductive material on the interlayer dielectric film and first conductive layer;
forming, on the film, a mask having a pattern corresponding to the first conductive layer; and
forming a second conductive layer by etching the film by using the mask.

3. A method according to claim 2, wherein the first conductive layer is a plug, and the second conductive layer is an interconnection.

4. A method according to claim 2, wherein the first conductive layer is an interconnection, and the second conductive layer is a plug.

5. A method according to claim 2, wherein at least one of the first and second conductive layers is formed by a material containing tungsten.

6. A method according to claim 2, wherein the first conductive layer is formed by a material containing tungsten, and the second conductive layer is formed by a material containing aluminum.

7. A semiconductor device fabrication method comprising:
forming a first interlayer dielectric film above a semiconductor substrate;
removing a predetermined region of the first interlayer dielectric film, and forming a film by depositing a conductive material so as to fill the removed region;
planarizing the film such that the film has substantially the same height as the first interlayer dielectric film, thereby burying the conductive material to form a conductive layer;
forming a second interlayer dielectric film on the first interlayer dielectric film and buried conductive layer;
forming, on the second interlayer dielectric film, a mask having a pattern which opens above part or a whole of an upper surface of the conductive layer;
exposing the upper surface of the conductive layer by etching the second interlayer dielectric film by using the mask; and
performing processing using a dilute aqueous choline solution on the upper surface of the exposed conductive layer.

8. A method according to claim 7, wherein the conductive layer is a plug.

9. A method according to claim 7, wherein the conductive layer is an interconnection.

10. A method according to claim 7, wherein the conductive layer is a plug and interconnection.

11. A method according to claim 7, wherein the conductive layer is formed by a material containing at least one of tungsten, titanium, and silicon.

12. A method according to claim 7, further comprising:
depositing a second conductive layer so as to fill a removed region of the second interlayer dielectric film; and
planarizing the second conductive layer such that the second conductive layer has substantially the same height as the second interlayer dielectric film.

13. A method according to claim 12, further comprising, performing processing using a dilute aqueous choline solution on an upper surface of the second conductive layer.

14. A method according to claim 12, wherein the second conductive layer is formed by a material containing at least one of tungsten, titanium, tantalum, aluminum, and copper.

15. A semiconductor device fabrication method comprising:
forming an interlayer dielectric film above a semiconductor substrate;
removing a plug formation region for forming a plug of the interlayer dielectric film;
removing an interconnection formation region for forming an interconnection of the interlayer dielectric film, thereby removing the interlayer dielectric film to a predetermined depth;
forming a film by depositing a conductive material so as to fill the plug formation region and interconnection formation region;
planarizing the film such that the film has substantially the same height as the interlayer dielectric film, thereby forming the plug and interconnection; and
processing the interconnection by using a dilute aqueous choline solution.

16. A method according to claim 15, wherein the layer formed by depositing the conductive material contains at least one of tungsten and titanium.

17. A method according to claim 1, wherein a concentration of the dilute aqueous choline solution is 0.01 to 10 wt %.

18. A method according to claim 7, wherein a concentration of the dilute aqueous choline solution is 0.01 to 10 wt %.

19. A method according to claim 15, wherein a concentration of the dilute aqueous choline solution is 0.01 to 10 wt %.

20. A method according to claim 17, wherein a temperature of the dilute aqueous choline solution is not less than 20° C.

21. A method according to claim 17, wherein the processing using the dilute aqueous choline solution removes an oxide film of the conductive material on a surface of the conductive layer.

22. A method according to claim 21, wherein the conductive layer contains tungsten.

23. A method according to claim 17, wherein processing is performed using dilute HF simultaneously with or sequentially before or after the processing using the dilute aqueous choline solution.

24. A semiconductor device fabrication method comprising:
performing processing using a dilute aqueous choline solution on an upper surface of a buried conductive layer in an interlayer dielectric film formed above a semiconductor substrate.
